(19) United States
(12) Patent Application Publication
(10) Pub. No.: US 2008/0191355 A1
(43) Pub. Date: Aug. 14, 2008

(54) SEMICONDUCTOR DEVICE HAVING BUFFER LAYER PATTERN AND METHOD OF FORMING SAME

(75) Inventor: Jeong-Ju PARK, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/103,180

(22) Filed: Apr. 15, 2008

Related U.S. Application Data
(63) Continuation of application No. 11/122,059, filed on May 5, 2005.

(30) Foreign Application Priority Data
Jun. 4, 2004 (KR) 10-2004-0041062

(51) Int. Cl. H01L 23/48; H01L 21/4763

(52) U.S. Cl. 257/760; 438/622; 257/E23.01; 257/E21.495

(57) ABSTRACT

A semiconductor device having a buffer layer pattern and a related method of manufacture are disclosed. The semiconductor device comprises at least two bit line patterns formed on a semiconductor substrate having a buried insulating interlayer. Each bit line pattern is formed of a bit line and a bit line capping layer pattern formed on the bit line. A buffer layer pattern is formed to cover one of the bit line patterns, and bit line spacers are formed on sidewalls of the remaining bit line patterns. A planarized insulating interlayer covers the buffer layer pattern and the bit line spacers. A bit line contact hole passing through the planarized insulating interlayer, the buffer layer pattern, and the bit line capping layer pattern, is formed on the bit line.

### CROSS-REFERENCE TO RELATED APPLICATION

This application is a continuation of U.S. patent application Ser. No. 11/122,059, filed on May 5, 2005, which claims priority to Korean patent application number 10-2004-0041062, filed Jun. 4, 2004. The subject matter of both of these applications is hereby incorporated by reference.

### BACKGROUND OF THE INVENTION

1. Field of the Invention

The present invention relates generally to a semiconductor device and a method of forming the same. More particularly, the present invention relates to a semiconductor device having a buffer layer pattern and a method of forming the same.

2. Description of the Related Art

In order to produce highly integrated, high speed semiconductor devices, modern semiconductor manufacturing processes often incorporate techniques aimed at improving the fidelity of patterns relative to design layouts. One such technique involves simplifying the manufacturing process by dividing each semiconductor device into array blocks containing a plurality of interconnection lines. The simplification of semiconductor manufacturing processes tends to increase the fidelity of the patterns.

The interconnection lines in the semiconductor devices are generally connected to each other by contact holes formed through one or more insulating interlayers using photolithography and etching processes. In many cases, however, the contact holes are not correctly aligned with the interconnection lines due to misalignment in the photolithography process. In addition, etching processes may deteriorate electrical characteristics of the semiconductor device through the misaligned contact holes. The misalignment of the photolithography process and the resulting misalignment of the contact holes to the interconnection lines causes even further problems where a design rule of the semiconductor device becomes smaller. In order to effectively address these problems, improved methods of manufacturing semiconductor devices are needed.

U.S. Pat. No. 6,121,085 to Chia-Wen Liang, et. al (the '085 patent) discloses a method of forming contact openings for a dynamic random-access memory (DRAM). According to the '085 patent, the method includes sequentially forming transistors, a first oxide layer, and bit lines on a semiconductor substrate. The first oxide layer insulates the transistors from the bit lines. A second oxide layer is formed to cover the bit lines, and a shielding layer having initial openings is formed on the second oxide layer. The initial openings define contact openings which are subsequently formed between adjacent transistors and bit lines. Sidewall spacers are formed on sidewalls of the initial openings, and using the sidewall spacers and the shielding layer as an etch mask, an etching process is sequentially performed on the first and second oxide layers, thereby forming the contact openings. The contact openings expose surfaces of source/drain regions of the transistors.

According to the method disclosed in the '085 patent, the diameter of the contact openings and the alignment of the initial openings determines whether the bit lines or the transistors are exposed by the etching process. As a result, variance in the formation of the initial openings can cause the bit lines and the transistors to be exposed through the contact openings in some regions on the semiconductor substrate, thereby causing defects to occur in the DRAM.

### SUMMARY OF THE INVENTION

According to selected embodiments of the present invention, a semiconductor device having a buffer layer pattern is provided. The buffer layer pattern prevents misalignments in a photolithography process from causing defects in the semiconductor device. In other words, the buffer layer secures a process margin between a bit line pattern and a bit line contact hole disposed on the bit line pattern.

According to one embodiment of the present invention, a semiconductor device comprises at least two bit line patterns formed on a semiconductor substrate having a buried insulating interlayer. Each bit line pattern comprises a bit line and a bit line capping layer pattern formed on the bit line. A buffer layer pattern is formed to cover one of the bit line patterns and bit line spacers are formed on sidewalls of bit line patterns that are not covered by the buffer layer pattern. A planarized insulating interlayer is formed to cover the buffer layer pattern, and a bit line contact hole is formed through the planarized insulating interlayer, the buffer layer pattern, and the bit line capping layer pattern. The bit line contact hole is formed on the bit line capping layer pattern covered by the buffer layer pattern.

According to another embodiment of the present invention, a method of forming a semiconductor device having a buffer layer pattern is provided. The method comprises forming a buried insulating interlayer on a semiconductor substrate and forming at least two bit line patterns on the buried insulating interlayer. Each bit line pattern comprises a bit line and a bit line capping layer pattern formed on the bit line. The method further comprises concurrently forming a buffer layer pattern to cover one of the bit line patterns, and bit line spacers on sidewalls of remaining bit line patterns. A planarized insulating interlayer covering the bit line patterns, the bit line spacers, and the buried insulating interlayer is then formed, and a bit line contact hole passing through the planarized insulating interlayer, the buffer layer pattern, and the bit line capping layer pattern is formed, thereby exposing the bit line.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIG. 1 is a top view of a semiconductor device according to one embodiment of the present invention;

FIG. 2 is a sectional view of semiconductor device taken along a line between I and I′ in FIG. 1 according to one embodiment of the present invention;

FIG. 3 is a sectional view of semiconductor device taken along a line between I and I′ in FIG. 1 according to another embodiment of the present invention;

FIGS. 4 through 9 are sectional views illustrating a method of forming a semiconductor device according to one embodiment of the present invention, the sectional views being taken along a line between I and I′ in FIG. 1; and,

FIGS. 10 through 12 are sectional views illustrating a method of forming a semiconductor device according to another embodiment of the invention, the sectional views being taken along a line between I and I′ in FIG. 1.

### DESCRIPTION OF THE EXEMPLARY EMBODIMENTS

Exemplary embodiments of the invention are described below with reference to the corresponding drawings. These embodiments are presented as teaching examples. The actual scope of the invention is defined by the claims that follow.

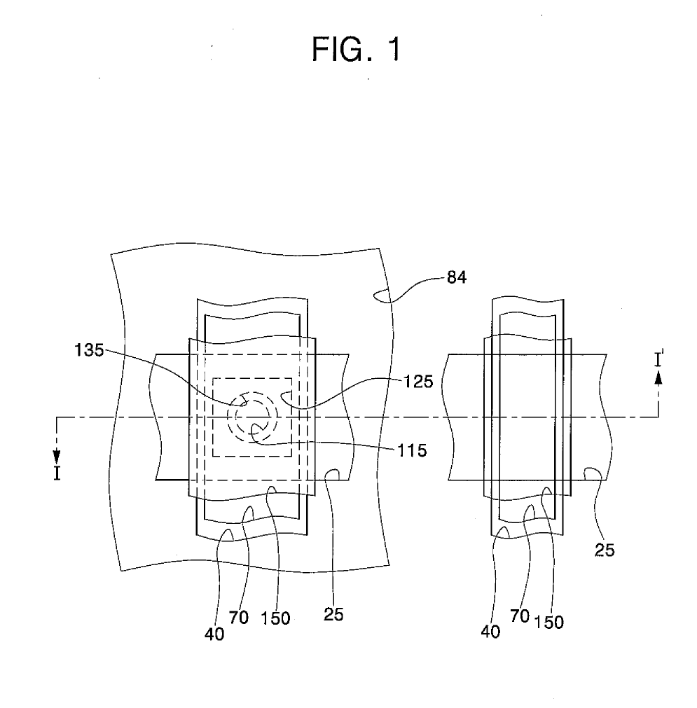

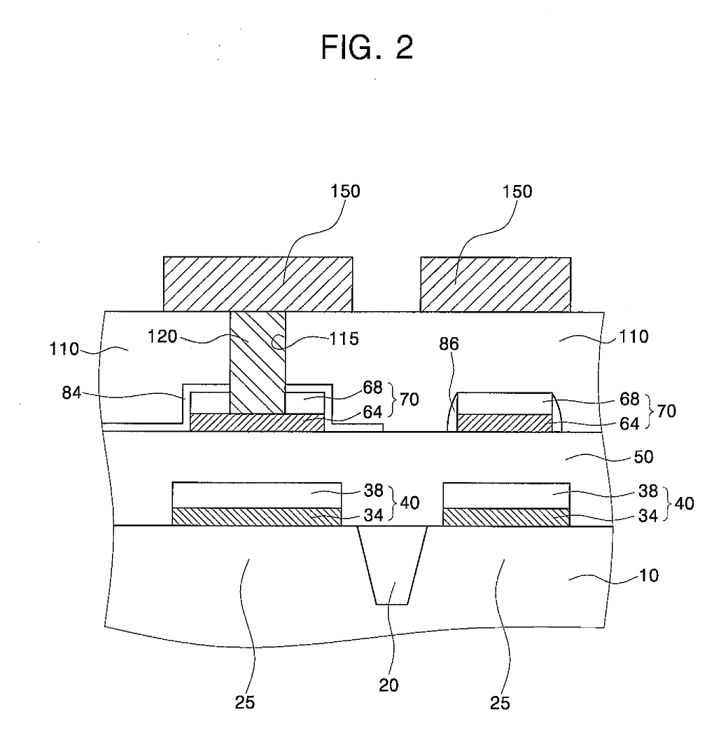

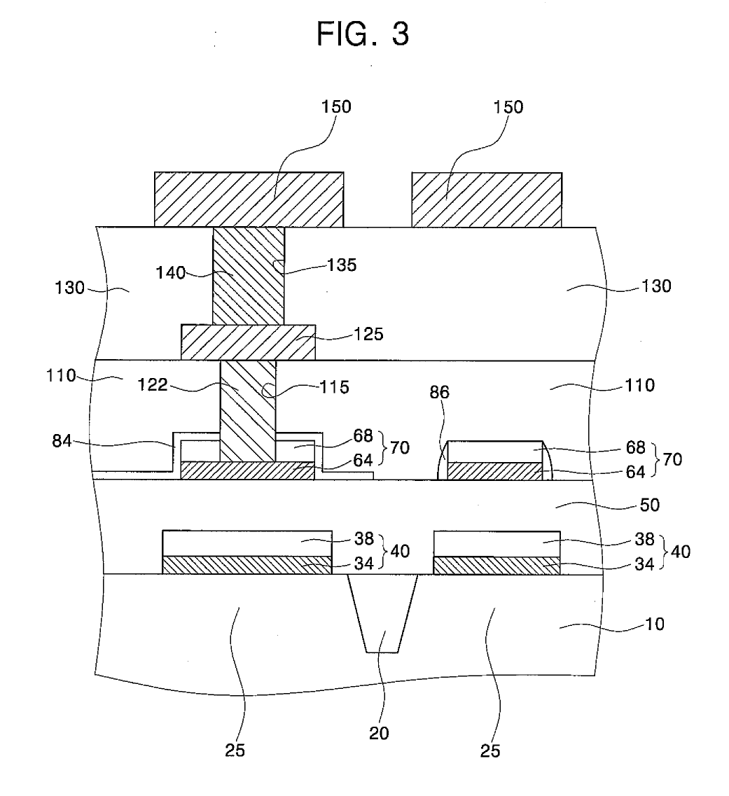

FIG. 1 is a top view of a semiconductor device according to an embodiment of the present invention and FIGS. 2 and 3 are sectional views of a semiconductor device taken along a line between I and I′ in FIG. 1 according to various embodiments of the present invention.

Referring to FIGS. 1 through 3, a device isolation layer 20 is formed in a semiconductor substrate 10. Device isolation layer 20 defines active regions 25. At least two gate patterns 40 are disposed on respective active regions 25. Each of gate patterns 40 includes a gate 34 and a gate capping layer pattern 38 formed on gate 34. Gate capping layer pattern 38 preferably comprises an insulating layer having a different etch rate from device isolation layer 20. In many cases gate capping layer pattern 38 comprises a nitride such as Si₃N₄. Gate 34 typically comprises N+ type doped polysilicon or sequentially stacked N+ type doped polysilicon and tungsten silicide (WSi). In some cases, gate spacers are formed on sidewalls of gate patterns 40.

A buried insulating interlayer 50 is formed to fill between gate patterns 40 and to cover semiconductor substrate 10. +Bit line patterns 70 are formed on buried insulating interlayer 50. The number of bit line patterns 70 is the same as the number of gate patterns 40. Bit line patterns 70 are disposed above respective gate patterns 40. Each of bit line patterns 70 includes a bit line 64 and a bit line capping layer pattern 68 formed on the bit line. Bit line capping layer pattern 68 typically comprises an insulating layer having a different etch rate from buried insulating interlayer 50. In many cases, bit line capping layer pattern 68 comprises a nitride such as Si₃N₄. Bit line 64 typically comprises N+ type doped polysilicon, or sequentially stacked N+ type doped polysilicon and a tungsten silicide (WSi). In some cases, bit line 64 comprises tungsten (W). Buried insulating interlayer 50 preferably comprises an insulating layer having a different etch rate from device isolation layer 20. For example, buried insulating interlayer 50 may comprise borophosphosilicate glass (BPSG).

One of bit line patterns 70 is covered with a buffer layer pattern 84, and the remaining bit line patterns 70 have bit line spacers 86 formed on sidewalls thereof. Buried insulating interlayer 50 preferably has a different etch rate from buffer layer pattern 84. A planarized insulating interlayer 110 covers the semiconductor substrate having buffer layer pattern 84 and bit line spacers 86. Planarized insulating interlayer 110 preferably comprises an insulating layer having the same etch rate as buried insulating interlayer 50. Planarized insulating interlayer 110 generally comprises BPSG or high density plasma (HDP). Bit line spacers 86 and buffer layer pattern 84 preferably comprise insulating layers having the same etch rate. Bit line spacers 86 and buffer layer pattern 84 typically comprise a nitride such as Si₃N₄.

A bit line contact hole 115 is formed on the bit line pattern 70 that is covered with buffer layer pattern 84. Bit line contact hole 115 penetrates planarized insulating interlayer 110, buffer layer pattern 84 and bit line capping layer pattern 68, thereby exposing bit line 64. A landing pad 120 is formed to fill bit line contact hole 115. Interconnection layer patterns 150 are formed on planarized insulating interlayer 110. One of the interconnection layer patterns 150 makes contact with landing pad 120, thereby electrically connecting that interconnection layer pattern 150 to the bit line 64 covered with buffer layer pattern 84. The number of interconnection layer patterns 150 is the same as the number of bit line patterns 70 and interconnection layer patterns 150 are disposed above respective bit line patterns 70. Landing pad 120 typically includes at least one metal, and interconnection layer patterns 150 preferably include aluminum (Al).

In cases where a distance between interconnection layer patterns 150 and bit line patterns 70 is greater than a thickness of planarized insulating interlayer 110, the invention can be realized by an embodiment shown in FIG. 3. The embodiment of FIG. 3 includes at least two gate patterns 40, bit line patterns 70, a buffer layer pattern 84, and bit line spacers 86 disposed on semiconductor substrate 10 as in FIG. 2. Gate patterns 40 and bit line patterns 70 are insulated from each other by buried insulating interlayer 50. Bit line patterns 70 are disposed on buried insulating interlayer 50 and the number of bit line patterns 70 is the same as the number of gate patterns 40. Buffer layer pattern 84 covers one of bit line patterns 70. Sidewalls of remaining bit line patterns 70 are covered with respective bit line spacers 86. Bit line spacers 86 preferably comprise an insulating layer having the same etch rate as buffer layer pattern 84. For example, bit line spacers 86 and buffer layer pattern 84 often both comprise a nitride. A planarized insulating interlayer 110 covers the semiconductor substrate having bit line spacers 86 and buffer layer pattern 84. Planarized insulating interlayer 110 preferably comprises an insulating layer having the same etch rate as buried insulating interlayer 50. Buried insulating interlayer 50 preferably comprises an insulating layer having a different etch rate from buffer layer pattern 84. In many cases buried insulating interlayer 50 comprises BPSG. Each of the bit line patterns 70 includes a bit line 64 and a bit line capping layer pattern 68 formed on the bit line. Each of gate patterns 40 includes a gate 34 and a gate capping layer pattern 38 formed on the gate.

A bit line contact hole 115 penetrates planarized insulating interlayer 110, buffer layer pattern 84 and bit line capping layer pattern 68, thereby exposing bit line 64. Bit line contact hole 115 is filled with a stud landing pad 122. A stud pad 125 is formed on planarized insulating interlayer 110 in contact with stud landing pad 122. Stud pad 125 and stud landing pad 122 are typically formed of N+ type doped polysilicon.

A protecting insulating interlayer 130 covering stud pad 125 is formed on planarized insulating interlayer 110. A stud contact hole 135 penetrating protecting insulating interlayer 130 is formed to expose stud pad 125. Protecting insulating interlayer 130 preferably comprises an insulating layer having the same etch rate as planarized insulating interlayer 110. In many cases, protecting insulating interlayer 130 comprises BPSG.

A stud contact hole pad 140 is formed to fill stud contact hole 135. Interconnection layer patterns 150 are formed on protecting insulating interlayer 130, and interconnection layer patterns 150 are formed above respective bit line patterns 70. One of interconnection layer patterns 150 contacts stud contact hole pad 140, thereby electrically connecting that interconnection layer pattern with the bit line 68 that is covered by buffer layer pattern 84. Stud contact hole pad 140 typically includes at least one metal and interconnection layer patterns 150 typically include aluminum (Al).

A method of forming a semiconductor device having a buffer layer pattern according to selected embodiments of the present invention will now be described.

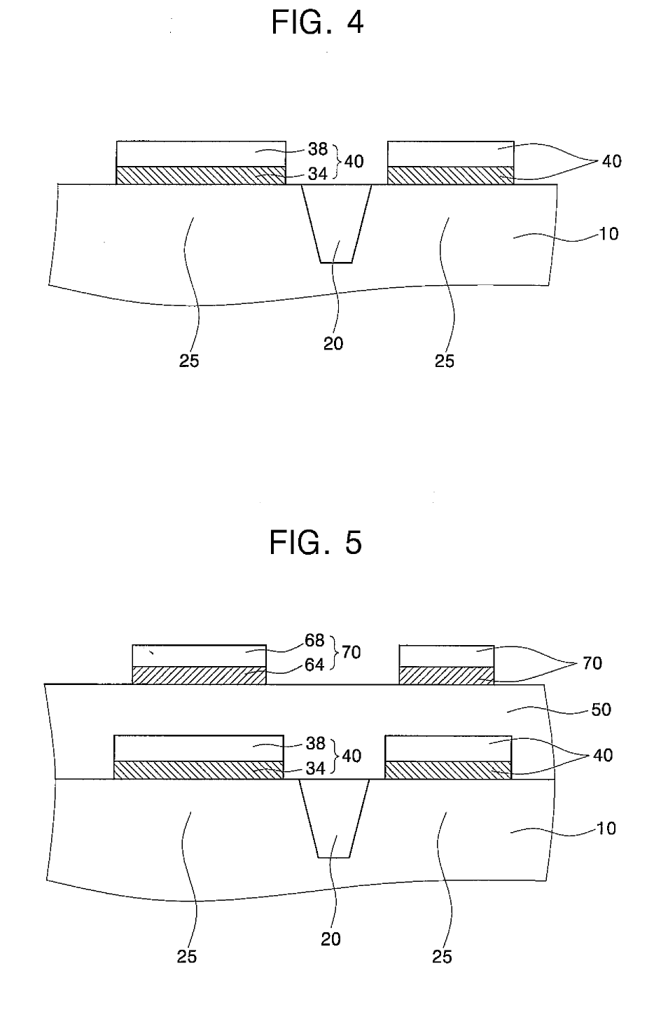

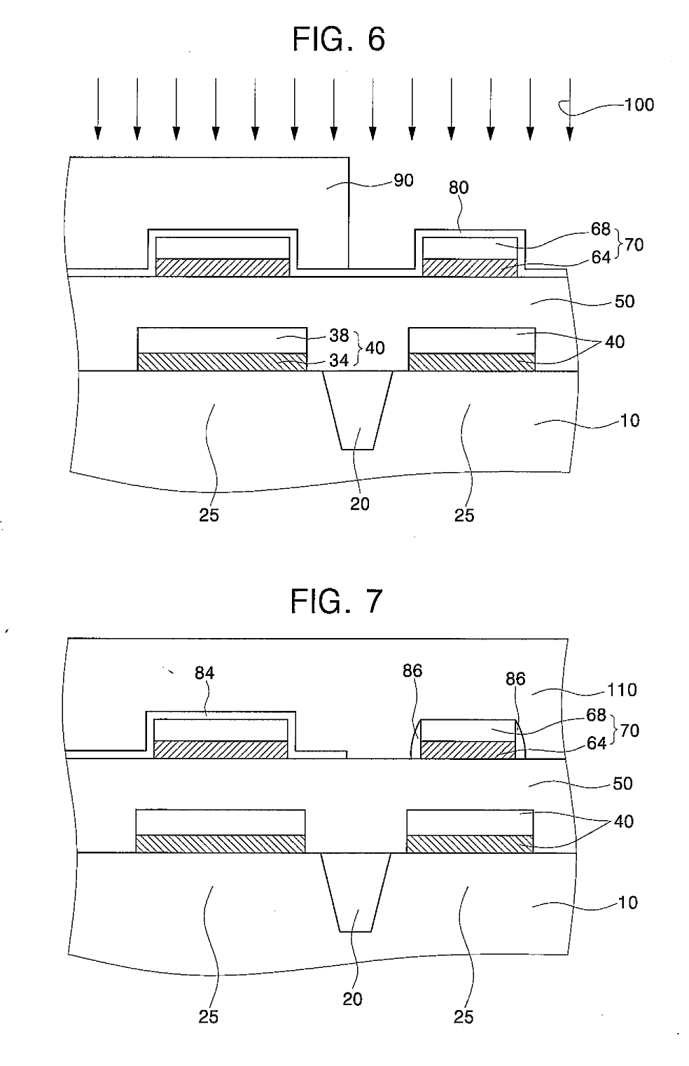

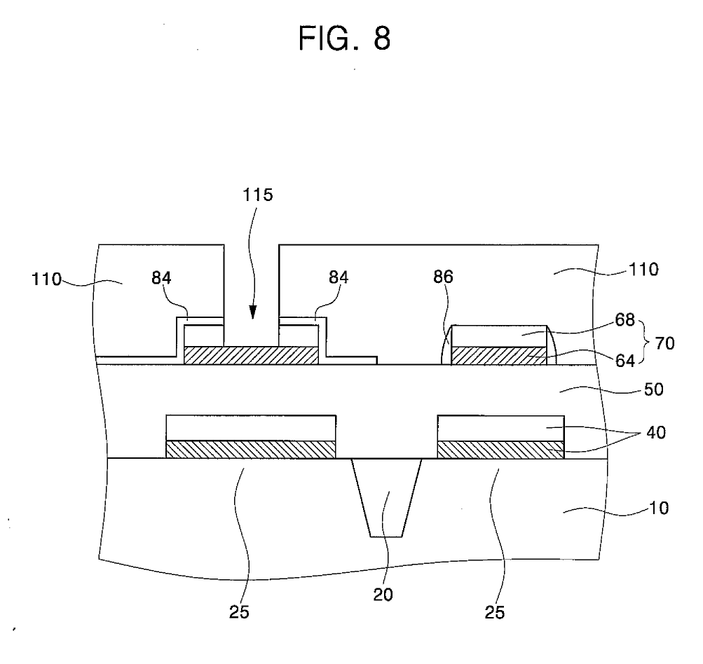

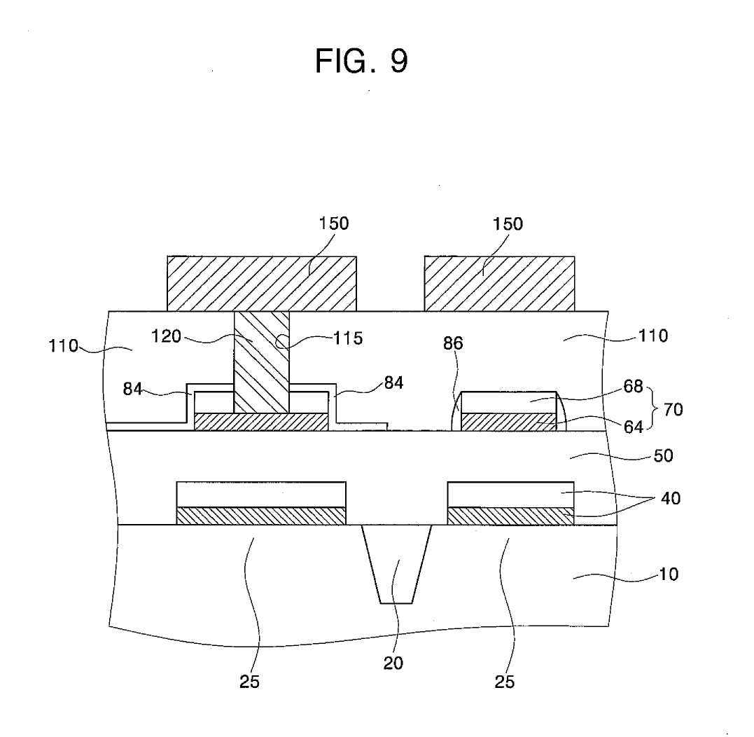

FIGS. 4 through 9 are sectional views illustrating a method of forming a semiconductor device according to an embodiment of the invention. The sectional views in FIGS. 4 through 9 are taken along a line between I and I′ in FIG. 1.

Referring to FIGS. 1, 4 and 5, a device isolation layer 20 is formed in a semiconductor substrate 10. Device isolation layer 20 defines active regions 25. At least two gate patterns 40 are formed on active regions 25. Each of gate patterns 40 comprises a gate 34 and a gate capping layer pattern 38 formed on the gate. Gate capping layer pattern 38 is preferably formed of an insulating layer having a different etch rate from device isolation layer 20. In many cases, gate capping layer pattern 38 is formed using a nitride such as Si₃N₄. Gate 34 typically comprises N+ type doped polysilicon or N+ type doped polysilicon with tungsten silicide (WSi) stacked thereon. In some cases, gate spacers are formed on sidewalls of gate patterns 40.

A buried insulating interlayer 50 covering gate patterns 40 is formed on semiconductor substrate 10. Bit line patterns 70 are formed on buried insulating interlayer 50. The number of bit line patterns 70 is the same as the number of gate patterns 40 and bit line patterns 70 are formed above respective gate patterns 40. Each of bit line patterns 70 generally comprises a bit line 64 and a bit line capping layer pattern 68 formed on the bit line. Bit line capping layer pattern 68 is preferably formed of an insulating layer having a different etch rate from buried insulating interlayer 50. Bit line capping layer pattern 68 is generally formed using a nitride such as Si₃N₄. Bit line 64 preferably comprises N+ type doped polysilicon or N+ type doped polysilicon with tungsten silicide (WSi) stacked thereon. Bit line 64 is generally formed using tungsten (W). Buried insulating interlayer 50 is preferably formed of an insulating layer having a different etch rate from device isolation layer 20. In many cases, buried insulating interlayer 50 is formed of BPSG.

Referring to FIGS. 1, 6 and 7, a buffer layer 80 is formed on the semiconductor substrate having bit line patterns 70. A photoresist pattern 90 is formed to cover one of the bit line patterns 70. By using photoresist pattern 90 as an etching mask, an etching process 100 is performed on buffer layer 80. Buffer layer 80 preferably comprises an insulating layer having a different etch rate from buried insulating interlayer 50. Buffer layer 80 is typically formed of a nitride.

Etching process 100 is performed to form a buffer layer pattern 84 and bit line spacers 86 on buried insulating interlayer 50. Buffer layer pattern 84 covers one of the bit line patterns 70, and bit line spacers 86 are formed on sidewalls of remaining bit line patterns 70. A planarized insulating interlayer 110 is formed to cover buffer layer pattern 84 and bit line spacers 86. Planarized insulating interlayer 110 preferably comprises an insulating layer having the same etch rate as buried insulating interlayer 50. Planarized insulating interlayer 110 is generally formed of BPSG or HDP.

Referring to FIGS. 1, 8, and 9, a bit line contact hole 115 penetrating planarized insulating interlayer 110, buffer layer pattern 84, and bit line capping layer pattern 68 is formed, thereby exposing bit line 64. Bit line contact hole 115 is generally formed using photolithography and etching processes. In cases where bit line contact hole 115 is formed such that it is misaligned with bit line pattern 70, bit line contact hole 115 may not expose bit line 64 and instead may expose buried insulating interlayer 50. However, even where bit line contact hole 115 is misaligned with bit line pattern 70, it is possible that the etching process will expose a portion of bit line 64 through bit line contact hole 115. This generally occurs where the etching process reacts process gases with bit line capping layer pattern 68 and buffer layer pattern 84, producing a polymer in a lower portion of bit line contact hole 115, and exposing at least part of bit line 64. As a result of this reaction, bit line contact hole 115 will typically have an upper sidewall perpendicular to a top surface of planarized insulating interlayer 110 and a sloped sidewall toward a middle portion of bit line contact hole 115 near a side portion of bit line 64. As such, bit line contact hole 115 does not expose buried insulating interlayer 50 at the side portion of bit line 64. Thus, the etching process has a process margin as large as the width of buffer layer pattern 84.

A landing pad 120 is formed to fill bit line contact hole 115, and interconnection layer patterns 150 are formed on planarized insulating interlayer 110. Interconnection layer patterns 150 are formed above respective bit line patterns 70 and the number of interconnection layer patterns 150 is the same as the number of bit line patterns 70. One of interconnection layer patterns 150 contacts landing pad 120 so as to be electrically connected to bit line 64. Landing pad 120 typically includes at least one metal, and interconnection layer patterns 150 generally includes aluminum (Al).

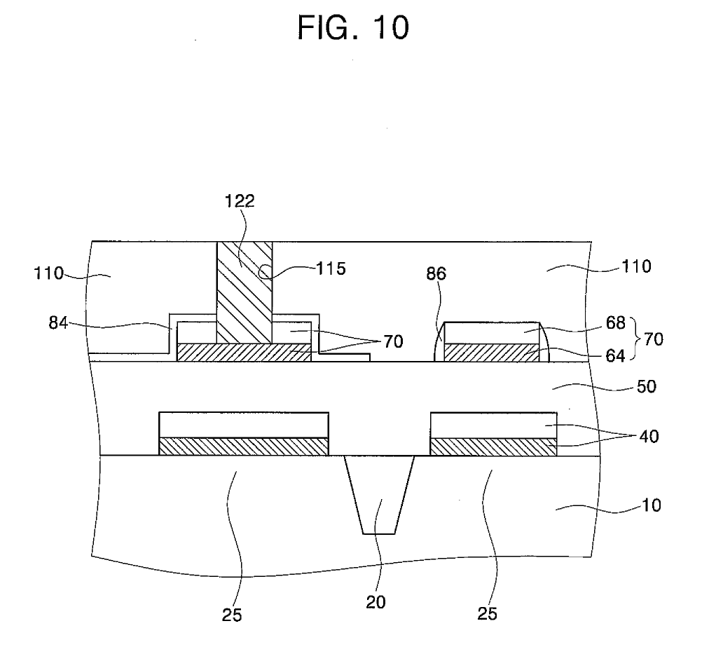

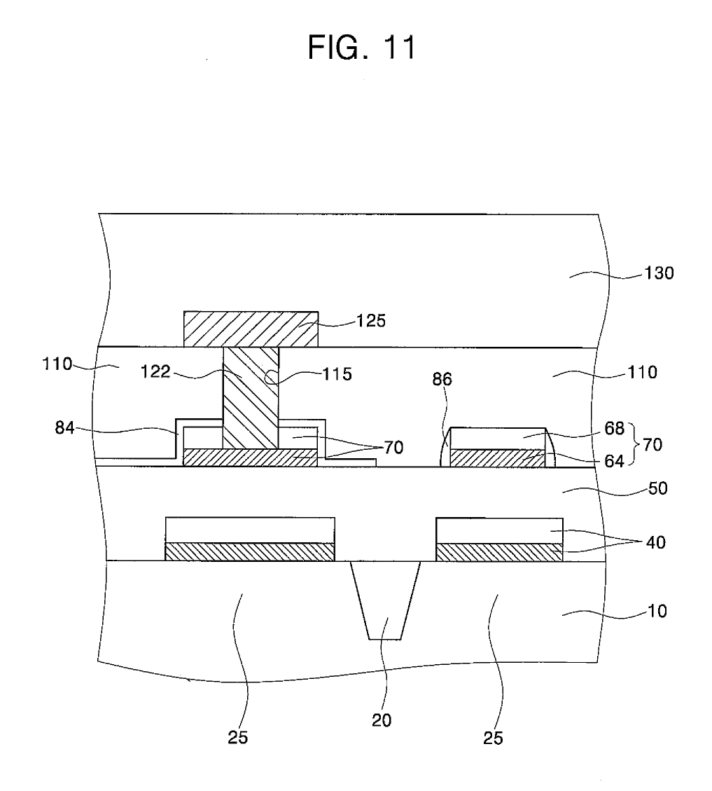

In a case where the distance between interconnection layer patterns 150 and bit line pattern 70 is greater than a thickness of planarized insulating interlayer 110, the method of forming a semiconductor device having buffer layer pattern 84 can be realized according to FIGS. 10 through 12.

FIGS. 10 through 12 are sectional views illustrating a method of forming a semiconductor device according to another embodiment of the present invention. The sectional views in FIGS. 10 through 12 are taken along a line between I and I′ in FIG. 1.

Referring to FIGS. 1, 10, and 11, a semiconductor substrate having a planarized insulating interlayer 110 is prepared as shown in FIG. 7. A bit line contact hole 115 penetrating planarized insulating interlayer 110, a buffer layer pattern 84 and a bit line capping layer pattern 68 is then formed, thereby exposing a bit line 64. Bit line contact hole 115 is filled with a stud landing pad 122. Stud landing pad 122 is typically formed using N+ type doped polysilicon. Bit line contact hole 115 is generally formed using photolithography and etching processes. In cases where bit line contact hole 115 is formed such that it is misaligned with bit line pattern 70, bit line contact hole 115 may not expose bit line 64 and instead may expose buried insulating interlayer 50. However, even where bit line contact hole 115 is misaligned with bit line pattern 70, it is possible that the etching process will expose a portion of bit line 64 through bit line contact hole 115. This generally occurs where the etching process reacts process gases with bit line capping layer pattern 68 and buffer layer pattern 84, producing a polymer in a lower portion of bit line contact hole 115, and exposing at least part of bit line 64. As a result of this reaction, bit line contact hole 115 will typically have an upper sidewall perpendicular to a top surface of planarized insulating interlayer 110 and a sloped sidewall toward a middle portion of bit line contact hole 115 near a side portion of bit line 64. As such, bit line contact hole 115 does not expose buried insulating interlayer 50 at the side portion of bit line 64. Thus, the etching process has a process margin as large as the width of buffer layer pattern 84.

A stud pad 125 is formed on planarized insulating interlayer 110 in contact with stud landing pad 122. A protecting insulating interlayer 130 is formed to cover stud pad 125 and planarized insulating interlayer 110. Both stud landing pad 122 and stud pad 125 are typically formed of N+ type doped polysilicon. Protecting insulating interlayer 130 is preferably formed using an insulating layer having the same etch rate as planarized insulating interlayer 110. Planarized insulating interlayer 110 is generally formed of BPSG.

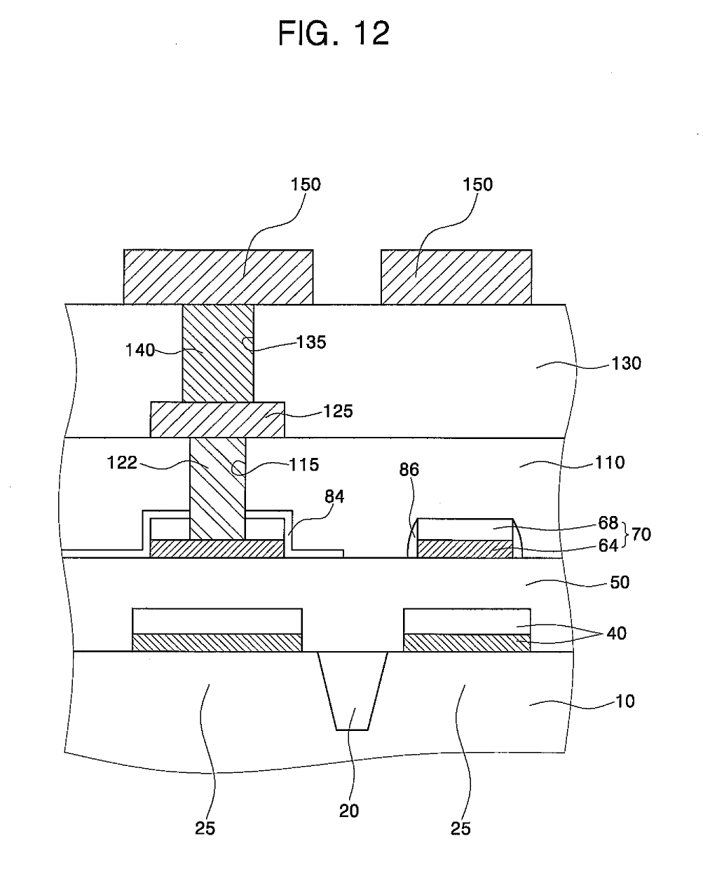

Referring to FIGS. 1, and 12, a stud contact hole 135 is formed to penetrate protecting insulating interlayer 130 and expose stud pad 125. Stud contact hole 135 is then filled with a stud contact hole pad 140. Interconnection layer patterns 150 are then disposed on protecting insulating interlayer 130. The number of interconnection layer patterns 150 is the same number as the number of bit line patterns 70. Interconnection layer patterns 150 are formed above respective bit line patterns 70 and one of the interconnection layer patterns 150 contacts stud contact hole pad 140. Stud contact hole pad 140 typically includes at least one metal, and interconnection layer patterns 150 generally include aluminum (Al). Thus, in a case where the distance between interconnection layer patterns 150 and the bit line pattern 70 is greater than the thickness of planarized insulating interlayer 110, interconnection layer patterns 150 can be electrically connected to bit line 64 through stud contact hole pad 140, stud pad 125, and stud landing pad 122.

As described above, in a case where a bit line contact hole is formed in a bit line pattern, a buffer layer pattern is formed to cover the bit line pattern, thereby securing a process margin against misalignment between the bit line contact hole and the bit line pattern. The resulting process margin is a function of the width of the buffer layer pattern. As a result, a semiconductor device having the buffer layer pattern prevents the bit line contact hole from exposing a gate pattern under the bit line pattern, thereby improving electrical characteristics of the semiconductor device.

According to selected embodiments of the present invention, a semiconductor device having a buffer layer pattern that includes at least two bit line patterns disposed on a semiconductor substrate having a buried insulating interlayer is provided. Each bit line pattern includes a bit line and a bit line capping layer pattern formed on the bit line. A buffer layer pattern covers one of the bit line patterns and bit line spacers are formed on sidewalls of remaining bit line patterns. A planarized insulating interlayer covers the buffer layer pattern and the bit line spacers. A bit line contact hole passing through the planarized insulating interlayer, the buffer layer pattern, and the bit line capping layer pattern, is formed on the bit line.

According to the other embodiments of the present invention, a semiconductor device having a buffer layer pattern that includes at least two bit line patterns disposed on a semiconductor substrate having a buried insulating interlayer is provided. Each bit line pattern includes a bit line and a bit line capping layer pattern formed on the bit line. A buffer layer pattern covers one of the bit line patterns and bit line spacers are formed on sidewalls of remaining bit line patterns. A planarized insulating interlayer covers the buffer layer pattern and the bit line spacers. A bit line contact hole passing through the planarized insulating interlayer, the buffer layer pattern, and the bit line capping layer pattern, is formed on the bit line. A stud landing pad fills the bit line contact hole and a stud pad is disposed on the planarized insulating interlayer in contact with the stud landing pad. A protecting insulating interlayer covering the stud pad is formed on the planarized insulating interlayer. A stud contact hole penetrates the protecting insulating interlayer and exposes the stud pad.

According to some embodiments of the present invention, a method of forming a semiconductor device having a buffer layer pattern is provided. The method comprises forming a buried insulating interlayer on a semiconductor substrate. The method further comprises forming at least two bit line patterns on a buried insulating interlayer. Each bit line pattern is formed to include a bit line and a bit line capping layer pattern formed on the bit line. A buffer layer pattern is formed to cover one of the bit line patterns and bit line spacers are formed on sidewalls of remaining bit line patterns. A planarized insulating interlayer is formed to cover the bit line patterns, the bit line spacers, and the buried insulating interlayer. A bit line contact hole passing through the planarized insulating interlayer, the buffer layer pattern and the bit line capping layer pattern is then formed, thereby exposing the bit line.

According to the other embodiments of the present invention, another method of forming a semiconductor device having a buffer layer pattern is provided. The method comprises forming a buried insulating interlayer on a semiconductor substrate. The method further comprises forming at least two bit line patterns on the buried insulating interlayer. Each bit line pattern is formed to include a bit line and a bit line capping layer pattern formed on the bit line. A buffer layer pattern is formed to cover one of the bit line patterns, and bit line spacers are formed on sidewalls of remaining bit line patterns. A planarized insulating interlayer covering the bit line patterns, the bit line spacers, and the buried insulating interlayer is formed. A bit line contact hole passing through the planarized insulating interlayer, the buffer layer pattern, and the bit line capping layer pattern is formed, thereby exposing the bit line. A stud landing pad filling the bit line contact hole is then formed. A stud pad is then formed on the planarized insulating interlayer in contact with the stud landing pad. A protecting insulating interlayer covering the stud pad and the planarized insulating interlayer is then formed. A stud contact hole penetrating the protecting insulating interlayer is then formed, thereby exposing the stud pad. A stud contact hole pad is then formed in the stud contact hole pad and interconnection layer patterns are formed on the protecting insulating layer above the bit line patterns. One of the interconnection layer patterns is in contact with the stud contact hole pad, thus connecting that interconnection layer pattern with the bit line below it.

What is claimed is:

1. A semiconductor device comprising:
a buried insulating interlayer disposed on a substrate;
a first bit line pattern and a second bit line pattern disposed on the buried insulating layer, wherein each of the first and the second bit line patterns comprises a bit line and a bit line capping layer disposed on the bit line;
a buffer layer pattern disposed on the bit line capping layer of the first bit line pattern and on sidewalls of the first bit line pattern;
a plurality of spacers disposed on first and second sidewalls of the second bit line pattern;
a planarized insulating interlayer disposed on the buffer layer pattern, the bit line capping pattern of the second bit line pattern, and the spacers; and
a bit line contact hole extending through the planarized insulating layer, the buffer layer pattern, and the bit line capping layer of the first bit line pattern.

2. The semiconductor device of claim 1, wherein the buffer layer pattern is conformably formed on the bit line capping layer of the first bit line pattern.

3. The semiconductor device of claim 1, wherein the buffer layer pattern is formed directly on the first bit line pattern.

4. The semiconductor device of claim 1, wherein the buffer layer pattern is conformably extended on the buried insulating interlayer.

5. The semiconductor device of claim 1, wherein the buried insulating interlayer and the planarized insulating interlayer are silicon oxide.

6. The semiconductor device of claim 1, wherein the bit line capping layer is silicon nitride.

7. The semiconductor device of claim 1, wherein the buffer layer and the spacers are silicon nitride.

8. The semiconductor device of claim 1, further comprising:
a landing pad filling in the bit line contact hole and connected to the bit line of the first bit line pattern; and
an interconnection layer pattern formed on the planarized insulating interlayer,
wherein the interconnection layer pattern is electrically connected to the landing pad.

9. The semiconductor device of claim 1, wherein the buffer layer pattern is formed on the first bit line pattern but not the second bit line pattern.

10. A method of forming a semiconductor device, the method comprising:
forming a buried insulating interlayer on a substrate;
forming a first bit line pattern and a second bit line pattern on the buried insulating layer, wherein each of the first and the second bit line patterns comprises a bit line and a bit line capping layer disposed on the bit line;
forming a buffer layer pattern on the bit line capping layer of the first bit line pattern and on sidewalls of the first bit line pattern;
forming spacers on first and second sidewalls of the second bit line pattern;
forming a planarized insulating interlayer on the buffer layer pattern, on the bit line capping layer of the second bit line pattern, and on the spacers; and
forming a bit line contact hole through the planarized insulating layer, the buffer layer pattern, and the bit line capping layer of the first bit line pattern.

11. The method of claim 10, wherein the buffer layer pattern is conformably formed on the bit line capping layer of the first bit line pattern.

12. The method of claim 10, wherein the buffer layer pattern is formed directly on the first bit line pattern.

13. The method of claim 10, wherein the buffer layer pattern is conformably extended on the buried insulating interlayer.

14. The method of claim 10, wherein the buried insulating interlayer and the planarized insulating interlayer are silicon oxide.

15. The method of claim 10, wherein the bit line capping layer is silicon nitride.

16. The method of claim 10, wherein the buffer layer and the spacers are silicon nitride.

17. The method of claim 10, further comprising:
forming a landing pad in the bit line contact hole, wherein the landing pad fills the bit line contact hole and is connected to the bit line of the first bit line pattern; and
forming an interconnection layer pattern on the planarized insulating interlayer,
wherein the interconnection layer pattern is electrically connected to the landing pad.

18. The method of claim 10, wherein the buffer layer pattern and the spacers are formed at the same time from a buffer layer deposited on the first and the second bit line patterns.

19. The method of claim 18, wherein the spacers are formed by etching a first portion of the buffer layer disposed on the second bit line pattern.

20. The method of claim 19, wherein the buffer layer pattern is formed from a second portion of the buffer film, wherein the second portion is not etched while the spacers are being formed.
